(19) United States
(12) Patent Application Publication
(10) Pub. No.: US 2022/0356028 A1
(43) Pub. Date: Nov. 10, 2022

(54) ROLLER FOR TRANSPORTING A FLEXIBLE SUBSTRATE, VACUUM PROCESSING APPARATUS, AND METHODS THEREFOR

(71) Applicant: Applied Materials, Inc., Santa Clara, CA (US)

(72) Inventors: Andreas SAUER, Grossostheim (DE); Annemarie HLADIK, Munster (DE); Bernhard KÖHLER, Biebergemund (DE); Thomas DEPPISCH, Aschaffenburg (DE); Claire ARMSTRONG, Gummersbach (DE); Wolfgang BUSCHBECK, Hanau (DE)

(21) Appl. No.: 17/307,216

(22) Filed: May 4, 2021

(51) Int. Cl. B65H 27/00; B65H 18/14; B65H 23/038

(52) U.S. Cl. CPC B65H 27/00; B65H 18/145; B65H 23/038; B65H 2301/5144; B65H 2404/1363; B65H 2301/5114; B65H 2404/18

(57) ABSTRACT

A roller for transporting a flexible substrate is described. The roller includes a main body having a plurality of gas supply slits provided in an outer surface of the main body. The plurality of gas supply slits extends in a direction of a central rotation axis of the roller. Further, the roller includes a sleeve provided circumferentially around and in contact with the main body. The sleeve has a plurality of gas outlets extending in a radial direction (R) and being provided above the plurality of gas supply slits.

### TECHNICAL FIELD

Embodiments of the present disclosure relate to rollers for transporting a flexible substrate. Further, embodiments of the disclosure relate to apparatuses and methods for flexible substrate processing, particularly coating of flexible substrates with thin layers, using a roll-to-roll process. In particular, embodiments of the disclosure relate to rollers employed for transportation of flexible substrates in apparatuses and methods for coating the flexible substrate with a stack of layers, e.g. for thin-film solar cell production, thin-film battery production, or flexible display production.

### BACKGROUND

Processing of flexible substrates, such as plastic films or foils, is in high demand in the packaging industry, semiconductor industries and other industries. Processing may consist of coating a flexible substrate with a material, such as a metal, a semiconductor and a dielectric material, etching and other processing actions conducted on a substrate for the respective applications. Systems performing this task typically include a coating drum, e.g. a cylindrical roller, coupled to a processing system with a roller assembly for transporting the substrate, and on which at least a portion of the substrate is coated.

For example, a coating process such as a CVD process, a PVD process or an evaporation process can be utilized for depositing thin layers onto flexible substrates. Roll-to-roll deposition apparatuses are understood in that a flexible substrate of a considerable length, such as one kilometer or more, is uncoiled from a supply spool, coated with a stack of thin layers, and recoiled again on a wind-up spool. In particular, in the manufacture of thin film batteries, e.g. lithium batteries, the display industry and the photovoltaic (PV) industry, roll-to-roll deposition systems are of high interest. For example, the increasing demand for flexible touch panel elements, flexible displays, and flexible PVmodules results in an increasing demand for depositing suitable layers in roll-to-roll coaters.

For achieving high quality coatings on flexible substrates, various challenges with respect to flexible substrate transportation have to be mastered. For example, providing an appropriate substrate tension as well as a good substrate-roller contact and substrate cooling during the processing of the moving flexible substrate under vacuum conditions remain challenging.

Accordingly, there is a continuous demand for improved substrate transportation rollers, improved roll-to-roll processing apparatuses and methods therefor.

### SUMMARY

In light of the above, a roller for transporting a flexible substrate, a vacuum processing apparatus for processing a flexible substrate, a method of manufacturing a roller for guiding a flexible substrate, a method of processing a flexible substrate, and a method of manufacturing a coated flexible substrate according to the independent claims are provided. Further aspects, advantages, and features are apparent from the dependent claims, the description, and the accompanying drawings.

According to an aspect of the present disclosure, a roller for transporting a flexible substrate is provided. The roller includes a main body having a plurality of gas supply slits provided in an outer surface of the main body. The plurality of gas supply slits extends in a direction of a central rotation axis of the roller. Further, the roller includes a sleeve provided circumferentially around and in contact with the main body. The sleeve has a plurality of gas outlets extending in a radial direction. The plurality of gas outlets is provided above the plurality of gas supply slits.

According to a further aspect of the present disclosure, a vacuum processing apparatus for processing a flexible substrate is provided. The vacuum processing apparatus includes a processing chamber including a plurality of processing units having at least one deposition unit. Further, the vacuum processing apparatus includes a roller according to any embodiments described herein for guiding the flexible substrate past the plurality of processing units. The roller is connected to gas supply for providing gas to the flexible substrate through the plurality of gas outlets of the roller.

According to another aspect of the present disclosure, a method of manufacturing a roller for guiding a flexible substrate is provided. The method includes producing a sleeve having a plurality of gas outlets by using laser drilling. Further, the method includes providing the sleeve circumferentially around and in contact with a main body of the roller having a plurality of gas supply slits provided in an outer surface of the main body, such that the plurality of gas outlets is arranged above the plurality of gas supply slits.

According to a further aspect of the present disclosure, a method of processing a flexible substrate is provided. The method includes guiding the flexible substrate past one or more processing units by using a roller for transporting the flexible substrate according to any embodiments described herein. Further, the method includes controlling a temperature of the flexible substrate by providing gas to the flexible substrate through the plurality of gas outlets of the roller.

According to another aspect of the present disclosure, a method of manufacturing a coated flexible substrate is provided. The method includes using at least one of a roller according to any embodiments described herein, a vacuum processing apparatus according to any embodiments described herein, and a method of processing a flexible substrate according to any embodiments described herein.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1A shows a schematic longitudinal sectional view of a roller according to embodiments described herein;

FIG. 1B shows a cross-sectional view along line A-A indicated in FIG. 1A;

FIG. 1C shows an enlarged portion of FIG. 1B;

FIG. 1D shows a schematic top view of a roller illustrating an arrangement of gas outlets according to embodiments described herein;

FIG. 1E shows an enlarged portion of FIG. 1C;

FIGS. 2A to 2C show schematic top views of a roller having different gas outlet densities according to embodiments described herein;

FIGS. 3A to 3C show schematic top views of a roller having different outlet diameters according to embodiments described herein;

FIG. 4 shows a schematic view of a vacuum processing apparatus according to embodiments described herein;

FIG. 5 shows a block diagram for illustrating a method of manufacturing a roller for guiding a flexible substrate according to embodiments described herein; and

FIG. 6 shows a block diagram for illustrating a method of processing a flexible substrate according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

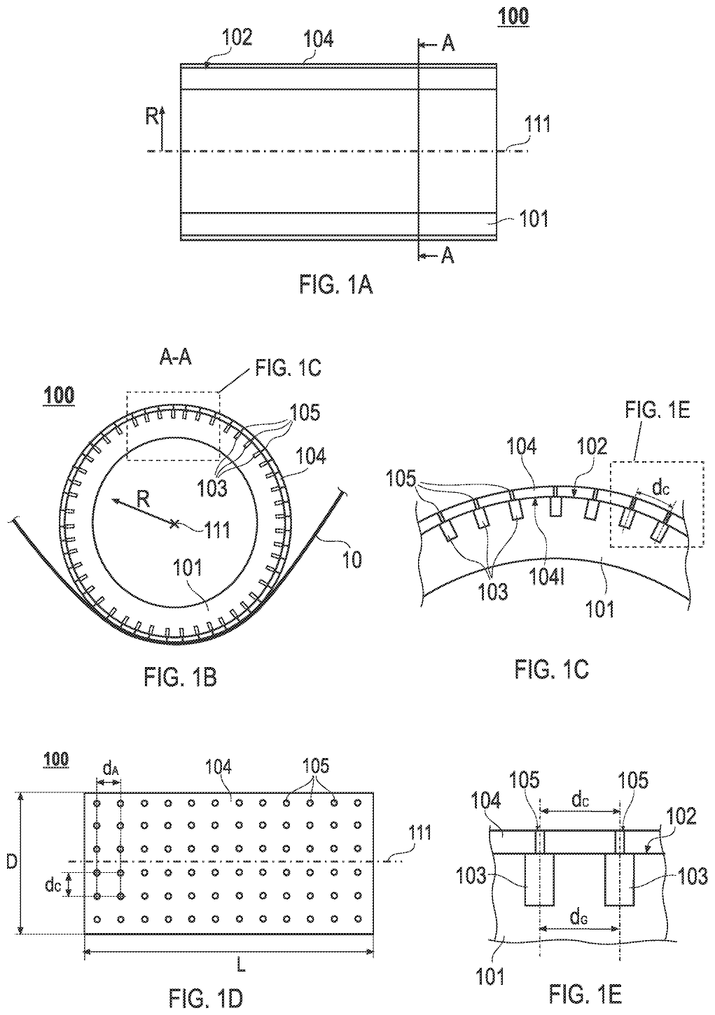

With exemplary reference to FIGS. 1A to 1E, a roller 100 for transporting a flexible substrate 10 according to the present disclosure is described. According to embodiments, which can be combined with any other embodiments described herein, the roller 100 includes a main body 101 having a plurality of gas supply slits 103 provided in an outer surface 102 of the main body 101. The plurality of gas supply slits 103 extend in a direction of a central rotation axis 111 of the roller 100. Further, the roller 100 includes a sleeve 104 provided circumferentially around and in contact with the main body 101. The sleeve includes a plurality of gas outlets 105. The plurality of gas outlets 105 extend in a radial direction R and are provided above the plurality of gas supply slits 103. In particular, as exemplarily shown in FIGS. 1B,1C and 1E, the plurality of gas outlets 105 is directly provided above the plurality of gas supply slits 103. More specifically, typically an inner surface 1041 of the sleeve 104 with the plurality of gas outlets 105 is in contact with the outer surface 102 of the main body 101 having the plurality of gas supply slits 103. Accordingly, each gas outlet of the plurality of gas outlets 105 is provided above a respective gas supply slit of the plurality of gas supply slits 103.

Accordingly, beneficially an improved roller for transporting a flexible substrate is provided. In particular, embodiments of the roller described herein provide for improved gas delivery to the flexible substrate for cooling the flexible substrate. Accordingly, cooling efficiency can be improved. Further, embodiments of the roller as described are less complex compared to other commercially available gas cooling rollers, such that production of the roller according to embodiments described herein is facilitated and costs can be reduced.

Before various further embodiments of the present disclosure are described in more detail, some aspects with respect to some terms used herein are explained.

In the present disclosure, a “roller” can be understood as a drum or a roller having a substrate support surface for contacting the flexible substrate. The expression “substrate support surface for contacting the flexible substrate” can be understood in that the outer surface of the roller, e.g. the outer surface of the sleeve as described herein, is configured for contacting the flexible substrate during the guiding or transportation of the flexible substrate. Typically, the support surface is a curved outer surface, particularly a cylindrical outer surface, of the roller. Accordingly, typically the roller is rotatable about a rotation axis and includes a substrate guiding region. Typically, the substrate guiding region is a curved substrate support surface, e.g. a cylindrically symmetric surface, of the roller. The curved substrate support surface of the roller may be adapted to be (at least partly) in contact with the flexible substrate during the guiding of the flexible substrate. The substrate guiding region may be defined as an angular range of the roller in which the substrate is in contact with the curved substrate support surface during the guiding of the substrate, and may correspond to the enlacement angle of the roller. For instance, the enlacement angle of the roller may be 1200 or more, particularly 180° or more, or even 2700 or more. According to some embodiments, which can be combined with other embodiments described herein, the roller 100 is cylindrical and has a length L of 0.5 m≤L≤8.5 m. Further, the roller 100 may have a diameter D of 1.0 m≤D≤3.0 m. Accordingly, beneficially the roller is configured for guiding and transporting flexible substrates having a large width.

According to some embodiments, which can be combined with other embodiments described herein, the roller may have one or more E-chucks (not explicitly shown). An E-chuck can be understood as a device configured for providing an electrostatic charge for holding a substrate by electrostatic force. In particular, the one or more E-chucks may hold the flexible substrate and/or provide an attraction force for holding the web in contact with the curved surface of the roller. Accordingly, a constant and homogenous contact force between the flexible substrate and the roller may be further improved.

In the present disclosure, a “flexible substrate” can be understood as a bendable substrate. For instance, the “flexible substrate” can be a “foil” or a “web”. In the present disclosure the term “flexible substrate” and the term “substrate” may be synonymously used. For example, the flexible substrate as described herein may be made of or include materials like PET, HC-PET, PE, PI, PU, TaC, OPP, BOOP, CPP, one or more metals (e.g. copper), paper, combinations thereof, and already coated substrates like Hard Coated PET (e.g HC-PET, HC-TaC) and the like. In some embodiments, the flexible substrate is a COP substrate provided with an index matched (IM) layer on both sides thereof. For example, the substrate thickness can be 1 μm or more and 1 mm or less, particularly 500 μm or less, or even 200 μm or less. The substrate width W_{S} can be 0.3 m≤W≤8 m. The substrate may be a transparent or non-transparent substrate.

In the present disclosure, a “main body” of the roller can be understood as a cylindrical body, particularly a cylindrical shell body of solid material. Typically, the main body is made of a material having a high thermal conductivity λ, particularly λ≥50 W/(m·K), more particularly μ≥100 W/(m·K). For instance, the main body can be made of a material including copper such as copper alloys. In particular, the main body can be made of copper. It is to be understood that alternatively the main body may be made of any other suitable material having high thermal conductivity λ.

In the present disclosure, a “gas supply slit” can be understood as a slit configured for supplying gas to a plurality of gas outlets as described herein. In particular, typically a “gas supply slit” as described herein is provided in an outer surface of the main body and extends parallel to a central rotation axis of the roller. Typically, the central rotation axis of the roller corresponds to the central rotation axis of the main body. Moreover, typically a “gas supply slit” as described herein is connected to a gas supply. According to embodiments which can be combined with other embodiments described herein, the distance d_{G} between gas supply slits in the circumferential direction can be selected from a range between a lower limit d_{GL} and an upper limit d_{GU}, i.e d_{GL}≤d_{G}≤d_{GU}. The distance d_{G} is exemplarily indicated in FIG. 1E. The lower limit d_{GL} can be d_{GL}=4 mm, particularly d_{GL}=6 mm, more particularly d_{G}=8 mm. The upper limit d_{GU} can be d_{GU}=10 mm, particularly d_{GU}=12 mm, more particularly d_{GU}=15 mm. For instance, the distance d_{G} can be 10 mm.

In the present disclosure, a “sleeve” can be understood as a sleeve being in contact with an outer surface of a main body as described herein. Accordingly, the sleeve can be a shell provided circumferentially around and in contact with the main body. Typically, during transportation of the flexible substrate, the sleeve is at least partially in contact with the flexible substrate. In particular, the sleeve can provide the substrate support surface as described herein. Typically, the sleeve is made of a metal sheet. The sleeve can have a thickness T selected from a range between a lower limit T_{L} and an upper limit T_{U}. i.e. T_{L}≤T≤T_{U}. The lower limit T_{L} can be T_{L}=0.5 mm, particularly T_{L}=1.0 mm, more particularly T_{L}=1.5 mm. The upper limit T_{U} can be T_{U}=2.0 mm, particularly T_{U}=2.5 mm, more particularly T_{U}=3.0 mm.

In the present disclosure, a “gas outlet” can be understood as an outlet configured for providing gas to a flexible substrate during substrate transportation by the roller as described herein. Accordingly, a gas outlet as described herein can be understood as a gas discharge hole. The outlet diameter Dₒᵤₜ of a gas outlet according to the present disclosure can be selected from a range between a lower limit D_{L} and an upper limit D_{U}. i.e. D_{L}≤D_{OUT}≤D_{U}. The lower limit D_{L} can be D_{L}=30 μm, particularly D_{L}=40 μm, more particularly D_{L}=60 μm. The upper limit D_{U} can be D_{U}=150 μm, particularly D_{U}=100 μm, more particularly D_{U}=80 μm. Typically, a gas outlet as described herein is created by using a laser drilling method. Laser drilling may also be referred to as laser firing. Typically, a “gas outlet” as described herein has a cylindrical inner surface having an inner diameter corresponding to the outlet diameter Dₒᵤₜ of the gas outlet as described herein. In other words, a “gas outlet” as described herein can be understood as a cylindrical outlet having a constant outlet diameter Dₒᵤₜ along the outlet axis, typically extending in the radial direction.

According to embodiments which can be combined with other embodiments described herein, the distance d_{C} between neighbouring gas outlets in the circumferential direction can be selected from a range between a lower limit d_{CL} and an upper limit d_{CU}, i.e d_{CL}≤≤d_{C}≤d_{CU}. The lower limit d_{CL} can be d_{CL}=4 mm, particularly d_{CL}=6 mm, more particularly d_{CL}=8 mm. The upper limit d_{CU} can be d_{CU}=10 mm, particularly d_{CU}=12 mm, more particularly d_{CU}=15 mm. For instance, the distance d_{C} can be 10 mm.

According to embodiments which can be combined with other embodiments described herein, the distance d_{A} between neighbouring gas outlets in the axial direction can be selected from a range between a lower limit d_{AL} and an upper limit d_{AU}, i.e d_{AL}≤d_{A}≤d_{AU}. The lower limit d_{AL} can be d_{A}=4 mm, particularly d_{AL}=6 mm, more particularly d_{AL}=8 mm. The upper limit d_{AL} can be d_{AL}=10 mm, particularly d_{AL}=12 mm, more particularly d_{AL}=15 mm. For instance, the distance d_{A} can be 10 mm.

According to embodiments which can be combined with other embodiments described herein, the distance d_{C} between neighbouring gas outlets in the circumferential direction corresponds to the distance d_{A} between neighbouring gas outlets in the axial direction, i.e. d_{C}=d_{A}. In other words, the plurality of gas outlets as described herein may be regularly distributed in the sleeve.

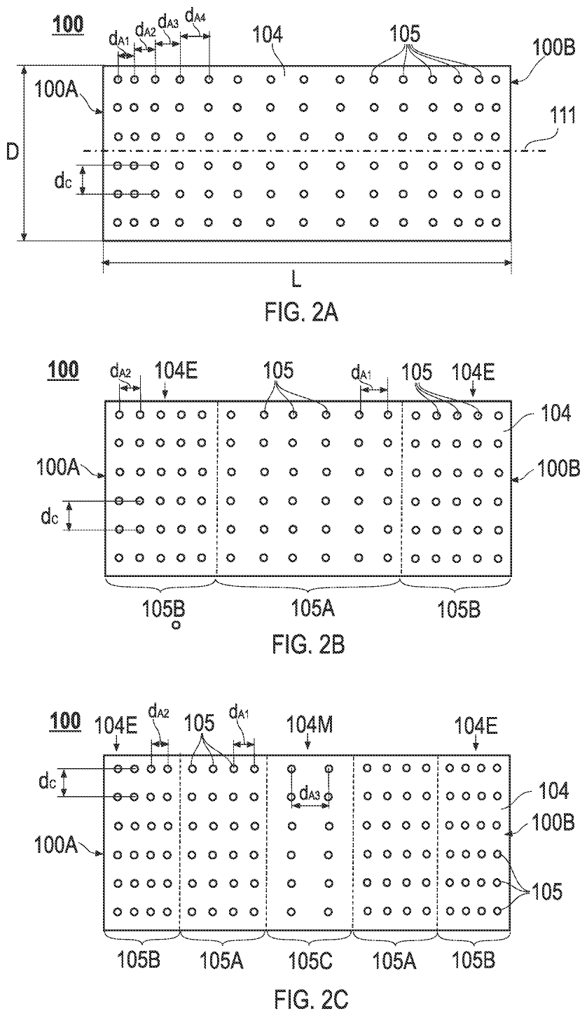

With exemplary reference to FIG. 2A showing a schematic top view of the roller 100, according to embodiments which can be combined with any other embodiments described herein, a density of the plurality of gas outlets 105 provided in the sleeve 104 changes towards at least one of a first axial end 100A and a second axial end 100B of the roller 100. In FIG. 2A, the length L of the roller, the diameter D of the roller, and the central rotation axis 111 of the roller are indicated. Typically, the density of the plurality of gas outlets 105 changes towards both axial ends of the roller 100, i.e. the first axial end 100A and the second axial end 100B. More specifically, the density of the plurality of gas outlets 105 provided in the sleeve 104 may symmetrically change towards the first axial end 100A and the second axial end 100B of the roller 100, particularly with respect to an axial middle between the first axial end 100A and the second axial end 100B. In particular, as shown in FIG. 2A, a distance d_{A} between neighbouring gas outlets may decrease towards the first axial end 100A and/or the second axial end 100B of the roller 100, exemplarily indicated by d_{A1}<d_{A2}<d_{A3}<d_{A4} in FIG. 2A, resulting in an increase of gas outlet density towards the first axial end 100A and/or the second axial end 100B of the roller 100.

In the present disclosure, the expression “density of the plurality of gas outlets” can be understood as the number of gas outlets per area. Accordingly, a higher density of gas outlets typically results in a shorter distance between neighboring gas outlets, particularly in the direction of the gas supply slits, as compared to gas outlets provided at a lower density. Typically, the gas supply slits are provided equally distributed in the circumferential direction. In other words, the distance between neighboring gas supply slits may be constant in the circumferential direction. Accordingly, typically the distance between neighboring gas outlets provided above the gas supply slits is also equally distributed in the circumferential direction. In other words, the distance between neighboring gas outlets may be constant in the circumferential direction. The distance d_{C} between neighbouring gas outlets 105 in the circumferential direction is exemplarily indicated in FIGS. 1C and 1D. Typically, the distance d_{C} is the distance between the central axis of the neighbouring gas outlets 105, as shown in FIG. 1E. Accordingly, typically the distance d_{G} between neighbouring gas supply slits 103 is the distance between the central axis of the neighbouring gas supply slits 103. In particular, as exemplarily shown in FIG. 1E, the distance d_{G} may substantially correspond to the distance d_{C}, i.e. d_{G}=d_{C}. The term “substantially correspond” is to be understood in that the effect due to the curvature of the roller on the difference between d_{G} and d_{C} can be neglected since the diameter D of the roller is much larger than the distance d_{G} between neighbouring gas supply slits as well as the distance d_{C} between neighbouring gas outlets in the circumferential direction, i.e. D>>d_{C} and D>>d_{G}. Accordingly, to be exact, the angle between the central axes of the neighbouring gas outlets 105 can be identical to the angle between the central axes of the neighbouring gas supply slits 103. As exemplarily shown in FIG. 1B, typically the number of gas outlets 105 in the circumferential direction corresponds to the number of gas supply slits 103. Alternatively, the number of gas outlets in the circumferential direction may be any integer multiple of the number of gas supply slits.

Accordingly, beneficially by changing the density of the plurality of gas outlets, the gas flow provided to the flexible substrate per area can be changed. In particular, by increasing the density of the plurality of gas outlets, the gas flow provided to the flexible substrate per area can be increased. Accordingly, by increasing the gas flow, the gas pressure on the flexible substrate can be increased. Consequently, by selecting the density distribution of the plurality of gas outlets, the gas flow per area and the gas pressure on the flexible substrate can be adjusted.

As exemplarily shown in FIG. 2A, according to embodiments which can be combined with any other embodiments described herein, the density of the plurality of gas outlets 105 provided in the sleeve 104 increases towards at least one of a first axial end 100A and a second axial end 100B of the roller 100. In particular, the density of the plurality of gas outlets 105 may gradually increase towards at least one of the first axial end 100A and the second axial end 100B. Typically, the density of the plurality of gas outlets 105 increases towards both axial ends of the roller 100, i.e. the first axial end 100A and the second axial end 100B. More specifically, the density of the plurality of gas outlets 105 provided in the sleeve 104 may symmetrically increase towards the first axial end 100A and the second axial end 100B of the roller 100, particularly with respect to an axial middle between the first axial end 100A and the second axial end 100B. Increasing the density of the plurality of gas outlets towards the axial ends of the roller can be beneficial for reducing or even avoiding a pressure drop towards the substrate edge. Accordingly, the substrate cooling efficiency can be improved. Further, the substrate cooling homogeneity can be improved.

Although not explicitly shown, it is to be understood that the density of the plurality of gas outlets 105 may also decrease towards at least one of a first axial end 100A and a second axial end 100B of the roller 100.

With exemplary reference to FIG. 2B, according to embodiments which can be combined with any other embodiments described herein, the plurality of gas outlets 105 include at least a first subgroup 105A of gas outlets 105 and a second subgroup 105B of gas outlets 105. The first subgroup 105A of gas outlets 105 has a first density. The second subgroup 105B of gas outlets 105 has a second density being different from the first density. In particular, the second density is higher than the first density. Further, as exemplarily shown in FIG. 2B, the second subgroup 105B of gas outlets 105 can be provided atone or both axial end portions 104E of the sleeve 104. For example, as exemplarily shown in FIG. 2B, a second distance d_{A2} between neighbouring gas outlets in the axial direction of the second subgroup 105B can be smaller than a first distance d_{A1} between neighbouring gas outlets in the axial direction of the first subgroup 105A.

With exemplary reference to FIG. 2C, according to embodiments which can be combined with any other embodiments described herein, the plurality of gas outlets 105 further includes a third subgroup 105C of gas outlets 105. The third subgroup 105C of gas outlets 105 has a third density being different from the first density and the second density. In particular, the third density can be lower than the first density and the second density. Typically, the third subgroup 105C of gas outlets 105 is provided in a middle portion 104M between axial end portions 104E of the sleeve 104. For example, as exemplarily shown in FIG. 2C, a third distance d_{A3} between neighbouring gas outlets in the axial direction of the third subgroup 105C can be larger than a first distance d_{A1} between neighbouring gas outlets in the axial direction of the first subgroup 105A and larger than a second distance d_{A} between neighbouring gas outlets in the axial direction of the second subgroup 105B.

Although not explicitly shown, from the exemplary embodiments shown in FIGS. 2A to 2C, it is to be understood that further subgroups of various gas outlet densities may be provided.

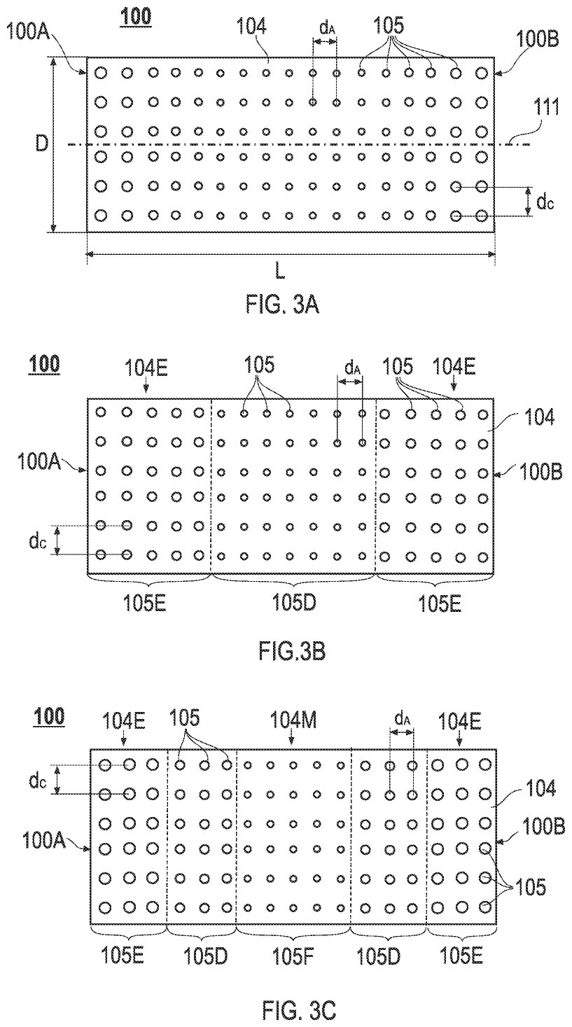

With exemplary reference to FIG. 3A, according to embodiments which can be combined with any other embodiments described herein, an outlet diameter of the plurality of gas outlets 105 changes towards at least one of a first axial end 100A and a second axial end 100A of the roller 100. Typically, the outlet diameter of the plurality of gas outlets 105 changes towards both axial ends of the roller 100, i.e. the first axial end 100A and the second axial end 100B. More specifically, the outlet diameter of the plurality of gas outlets 105 provided in the sleeve 104 may symmetrically change towards the first axial end 100A and the second axial end 100B of the roller 100, particularly with respect to an axial middle between the first axial end 100A and the second axial end 100B.

Accordingly, beneficially by changing the outlet diameter of the plurality of gas outlets, the gas flow provided to the flexible substrate per area can be changed. In particular, by increasing the outlet diameter of the plurality of gas outlets, the gas flow provided to the flexible substrate per area can be increased. Accordingly, by increasing the gas flow, the gas pressure on the flexible substrate can be increased. Consequently, by selecting the outlet diameter distribution of the plurality of gas outlets, the gas flow per area and the gas pressure on the flexible substrate can be adjusted.

According to embodiments which can be combined with any other embodiments described herein, the outlet diameter of the plurality of gas outlets 105 increases towards at least one of a first axial end 100A and a second axial end 100B of the roller 100. In particular, the outlet diameter of the plurality of gas outlets 105 may gradually increase towards at least one of the first axial end 100A and the second axial end 100B. Typically, the outlet diameter of the plurality of gas outlets 105 increases towards both axial ends of the roller 100, i.e. the first axial end 100A and the second axial end 100B. More specifically, the outlet diameter of the plurality of gas outlets 105 provided in the sleeve 104 may symmetrically increase towards the first axial end 100A and the second axial end 100B of the roller 100, particularly with respect to an axial middle between the first axial end 100A and the second axial end 100B. Increasing the outlet diameter of the plurality of gas outlets towards the axial ends of the roller can be beneficial for reducing or even avoiding a pressure drop towards the substrate edge. Accordingly, the substrate cooling efficiency can be improved. Further, the substrate cooling homogeneity can be improved.

Although not explicitly shown, it is to be understood that the outlet diameter of the plurality of gas outlets 105 may also decrease towards at least one of a first axial end 100A and a second axial end 100B of the roller 100.

With exemplary reference to FIG. 3B, according to embodiments which can be combined with any other embodiments described herein, the plurality of gas outlets 105 include at least a fourth subgroup 105D of gas outlets 105 and a fifth subgroup 105E of gas outlets 105. The fourth subgroup 105D of gas outlets 105 has a first outlet diameter. The fifth subgroup 105E of gas outlets 105 has a second outlet diameter being different from the first outlet diameter. In particular, the second outlet diameter is larger than the first outlet diameter. Typically, the fifth subgroup 105E of gas outlets 105 is provided at one or both axial end portions 104E of the sleeve 104.

With exemplary reference to FIG. 3C, according to embodiments which can be combined with any other embodiments described herein, the plurality of gas outlets 105 further includes a sixth subgroup 105F of gas outlets 105. The sixth subgroup 105F of gas outlets 105 has a third outlet diameter being different from the first outlet diameter and the second outlet diameter. In particular, the third outlet diameter can be smaller than the first outlet diameter of the fourth subgroup 105D of gas outlets 105. Additionally, the third outlet diameter can be smaller than the second outlet diameter of the fifth subgroup 105E of gas outlets 105. Typically, the sixth subgroup 105F of gas outlets 105 are provided in a middle portion between axial end portions 104E of the sleeve 104.

Although not explicitly shown, from the exemplary embodiments shown in FIGS. 3A to 3C, it is to be understood that further subgroups of various gas outlet diameters may be provided.

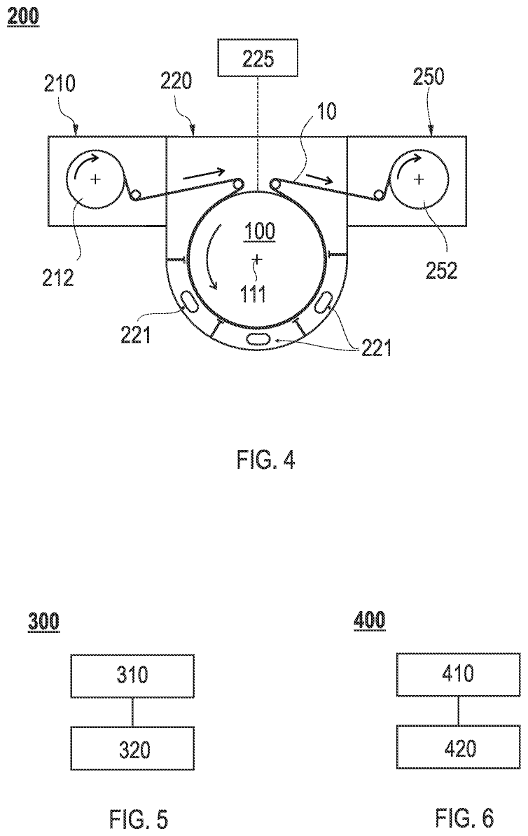

With exemplary reference to FIG. 4, a vacuum processing apparatus 200 according to the present disclosure is described. According to embodiments, which can be combined with any other embodiments described herein, the vacuum processing apparatus 200 includes a processing chamber 220 including a plurality of processing units 221. The plurality of processing units 221 includes at least one deposition unit. Further, the vacuum processing apparatus 200 includes a roller 100 according to any embodiments described herein for guiding the flexible substrate past the plurality of processing units 221. As schematically shown in FIG. 4, the roller 100 is connected to gas supply 225. Typically, the gas supply 225 is configured for supplying a cooling gas to the roller 100, such that the cooling gas can be provided to the flexible substrate through the plurality of gas outlets 105 as described herein.

As exemplarily shown in FIG. 4, typically the vacuum processing apparatus 200 is a roll-to-roll processing system. The roller 100 according to any embodiments described herein can be a processing drum or coating drum of the vacuum processing apparatus. According to embodiments, which can be combined with any other embodiments described herein, the vacuum processing apparatus 200 includes a first spool chamber 210 housing a storage spool 212 for providing the flexible substrate 10.

Additionally, the vacuum processing apparatus 200 includes the processing chamber 220 arranged downstream from the first spool chamber 210. Typically, the processing chamber 220 is a vacuum chamber and includes the plurality of processing units 221. The plurality of processing units 221 include at least one deposition unit. Accordingly, in the present disclosure, a “processing chamber” can be understood as a chamber having at least one deposition unit for depositing material on a substrate. Accordingly, the processing chamber may also be referred to as a deposition chamber. The term “vacuum”, as used herein, can be understood in the sense of a technical vacuum having a vacuum pressure of less than, for example, 10 mbar. Typically, the pressure in a vacuum chamber as described herein may be between 10⁻⁵ mbar and about 10⁻⁸ mbar, more typically between 10⁻⁵ mbar and 10⁻⁷ mbar, and even more typically between about 10⁻⁶ mbar and about 10⁻⁷ mbar.

As exemplarily shown in FIG. 4, the plurality of processing units may be arranged in a circumferential direction around the roller 100. As the roller 100 rotates, the flexible substrate 10 is guided past the processing units which face toward the curved substrate support surface of the roller, so that the surface of the flexible substrate can be processed while being moved past the processing units at a predetermined speed. For example, the plurality of processing units may include one or more units selected from the group consisting of: a deposition unit, an etching unit, and a heating unit. A deposition unit of the vacuum processing apparatus as described herein can be a sputter deposition unit, e.g. an AC (alternating current) sputter source or a DC (direct current) sputter source, a RF (radio frequency) sputter source, a MF (middle frequency) sputter source, a pulsed sputter source, a pulsed DC sputter source, a magnetron sputter source, a reactive sputter source, a CVD deposition unit, a PECVD deposition unit, a PVD deposition unit or another suitable deposition unit. It is to be understood that typically a deposition unit as described herein is adapted for depositing a thin film on a flexible substrate, e.g., to form a flexible display device, a touch-screen device component, or other electronic or optical devices. A deposition unit as described herein can be configured for depositing at least one material selected from the group of conductive materials, semi-conductive material, dielectric materials, or isolating materials.

Additionally, as exemplarily shown in FIG. 4, the vacuum processing apparatus 200 may include a second spool chamber 250 arranged downstream from the processing chamber 220. The second spool chamber 250 houses a wind-up spool 252 for winding the flexible substrate 10 thereon after processing.

With exemplary reference to the block diagram shown in FIG. 5, a method 300 of manufacturing a roller for guiding a flexible substrate according to the present disclosure is described. According to embodiments, which can be combined with any other embodiments described herein, the method includes producing (represented by block 310 in FIG. 5) a sleeve 104 having a plurality of gas outlets 105 by using laser drilling. Laser drilling may also be referred to as laser firing. Further, the method includes providing (represented by block 320 in FIG. 5) the sleeve 104 circumferentially around and in contact with a main body 101 of the roller 100 having a plurality of gas supply slits 103 provided in an outer surface of the main body 101, such that the plurality of gas outlets 105 are arranged above the plurality of gas supply slits 103.

With exemplary reference to the block diagram shown in FIG. 6, a method 400 of processing a flexible substrate according to the present disclosure is described. According to embodiments, which can be combined with any other embodiments described herein, the method includes guiding (represented by block 410 in FIG. 6) the flexible substrate 10 past one or more processing units 221 by using a roller 100 for transporting the flexible substrate 10 according to any embodiments described herein. Further, the method includes controlling (represented by block 420 in FIG. 6) a temperature of the flexible substrate 10 by providing gas to the flexible substrate through the plurality of gas outlets 105 of the roller 100.

In view of the embodiments described herein, it is to be understood that according to an aspect of the present disclosure, a method of manufacturing a coated flexible substrate can be provided. The method includes using at least one of a roller 100 according to any embodiments described herein, a vacuum processing apparatus 200 according to any embodiments described herein, and a method 400 of processing a flexible substrate according to any embodiments described herein.

In view of the above, it is to be understood that compared to the state of the art, embodiments as described herein provide for improved flexible substrate transportation, improved cooling of the flexible substrate during substrate processing such that better processing results, e.g. higher coating quality can be obtained.

While the foregoing is directed to embodiments, other and further embodiments may be devised without departing from the basic scope, and the scope is determined by the claims that follow.

1. A roller for transporting a flexible substrate, comprising
a main body having a plurality of gas supply slits provided in an outer surface of the main body, the plurality of gas supply slits extending in a direction of a central rotation axis of the roller; and
a sleeve provided circumferentially around and in contact with the main body, the sleeve having a plurality of gas outlets extending in a radial direction (R) and being provided above the plurality of gas supply slits.

2. The roller of claim 1, wherein a density of the plurality of gas outlets changes towards at least one of a first axial end and a second axial end of the roller.

3. The roller of claim 1, wherein the density of the plurality of gas outlets increases, particularly gradually increases, towards at least one of a first axial end and a second axial end of the roller.

4. The roller of claim 1, wherein the plurality of gas outlets comprises at least a first subgroup of gas outlets having a first density and a second subgroup of gas outlets having a second density being different from the first density.

5. The roller of claim 4, wherein the second density is higher than the first density, and wherein the second subgroup of gas outlets is provided at one or both axial end portions of the sleeve.

6. The roller of claim 4, the plurality of gas outlets further comprising a third subgroup of gas outlets having a third density being different from the first density and the second density, particularly the third density being lower than the first density and the second density, and the third subgroup of gas outlets being provided in a middle portion between axial end portions of the sleeve.

7. The roller of claim 1, wherein an outlet diameter of the plurality of gas outlets changes towards at least one of a first axial end and a second axial end of the roller.

8. The roller of claim 1, wherein an outlet diameter of the plurality of gas outlets increases, particularly gradually increases, towards at least one of a first axial end and a second axial end of the roller.

9. The roller of claim 1, wherein the plurality of gas outlets comprises at least a fourth subgroup of gas outlets having a first outlet diameter and a fifth subgroup of gas outlets having a second outlet diameter being different from the first outlet diameter.

10. The roller of claim 9, wherein the second outlet diameter is larger than the first outlet diameter, and wherein the fifth subgroup of gas outlets is provided at one or both axial end portions of the sleeve.

11. The roller of claim 9, the plurality of gas outlets further comprising a sixth subgroup of gas outlets having a third outlet diameter being different from the first outlet diameter and the second outlet diameter, particularly the third outlet diameter being smaller than the first outlet diameter and the second outlet diameter, and the sixth subgroup of gas outlets being provided in a middle portion between axial end portions of the sleeve.

12. The roller of claim 1, wherein the main body is a cylinder made of a material comprising copper, and wherein the sleeve is made of a metal sheet.

13. A vacuum processing apparatus for processing a flexible substrate, comprising:
a processing chamber comprising a plurality of processing units comprising at least one deposition unit,
and a roller according to claim 1 for guiding the flexible substrate past the plurality of processing units, the roller being connected to a gas supply.

14. A method of manufacturing a roller for guiding a flexible substrate, comprising
producing a sleeve having a plurality of gas outlets by using laser drilling; and
providing the sleeve circumferentially around and in contact with a main body of the roller having a plurality of gas supply slits provided in an outer surface of the main body such that the plurality of gas outlets are arranged above the plurality of gas supply slits.

15. A method of processing a flexible substrate, comprising
guiding the flexible substrate past one or more processing units (221) by using a roller for transporting the flexible substrate according to claim 1; and
controlling a temperature of the flexible substrate by providing gas to the flexible substrate through the plurality of gas outlets of the roller.

16. A method of manufacturing a coated flexible substrate, comprising using at least one of a roller according to claim 1, a vacuum processing apparatus according to claim 13, and a method of processing a flexible substrate according to claim 15.
